(19) United States
(12) Patent Application Publication
(10) Pub. No.: US 2024/0266265 A1
(43) Pub. Date: Aug. 8, 2024

(54) SEMICONDUCTOR DEVICE

(71) Applicant: FUJI ELECTRIC CO., LTD., Kawasaki-shi (JP)

(72) Inventors: Mai SAITO, Matsumoto-city (JP); Naoyuki KANAI, Matsumoto-city (JP)

(73) Assignee: FUJI ELECTRIC CO., LTD., Kawasaki-shi (JP)

(21) Appl. No.: 18/396,224

(22) Filed: Dec. 26, 2023

(30) Foreign Application Priority Data
Feb. 7, 2023 (JP) 2023-016798

(51) Int. Cl. H01L 23/498; H01L 23/00

(52) U.S. Cl. CPC H01L 23/49811; H01L 24/48; H01L 24/32; H01L 24/73; H01L 2224/32225; H01L 2224/48091; H01L 2224/48245; H01L 2224/73265

(57) ABSTRACT

A semiconductor device includes a semiconductor element, a terminal to which a wire is coupled, a housing surrounding the semiconductor element and a coupling portion of the terminal, the coupling portion of the terminal being coupled to the wire, and an encapsulant sealing an internal space surrounded by the housing, in which the terminal includes a recess-shaped or protrusion-shaped coupling region coupled to the wire.

### CROSS REFERENCE TO RELATED APPLICATION

This Application is based on, and claims priority from, Japanese Patent Application No. 2023-016798, filed on Feb. 7, 2023, the entire contents of which are incorporated herein by reference.

### BACKGROUND

### Technical Field

The present disclosure relates to semiconductor devices.

### Related Art

Japanese Patent Application Laid-Open Publication No. 2019-114618 discloses a technique for reducing spread of detachment that occurs at an interface between a die pad and a molded resin material. Specifically, Japanese Patent Application Laid-Open Publication No. 2019-114618 discloses a die pad with a surface. The surface of the die pad includes a chip mounting portion, a wire coupling portion, and a detachment-spread-prevention groove. On the chip mounting portion, a semiconductor chip is mounted. The wire coupling portion is coupled to a wire. The detachment-spread-prevention groove separates the chip mounting portion and the wire coupling portion from each other.

Japanese Patent Application Laid-Open Publication No. 2018-157023 discloses a technique for reducing wire disconnection in a semiconductor device without covering a coupling portion, which is coupled to a wire, with a film other than that of a molded resin material. Specifically, Japanese Patent Application Laid-Open Publication No. 2018-157023 discloses a technique for forming a roughened region on a semiconductor device. The semiconductor device includes a wire and a molded resin material. The wire is electrically connected to a coupling portion of a lead of a lead frame. The molded resin material encapsulates the wire and a part of the lead including the coupling portion. The roughened region is formed on a part of the lead that is encapsulated in the molded resin material and that is spaced apart from, and surrounds, the coupling portion. The roughened region has unevenness on the order of micrometers.

Semiconductor devices exist that include a housing surrounding an internal space in which a semiconductor element and a terminal are disposed, the internal space being sealed with an encapsulant in a state in which the terminal is coupled to a wire. However, in these semiconductor devices, some problems occur when the technique that is disclosed in Japanese Patent Application Laid-Open Publication No. 2019-114618 or in Japanese Patent Application Laid-Open Publication No. 2018-157023 is used to prevent spreading of detachment toward a coupling portion at which a terminal and a wire are coupled to each other. When the technique that is disclosed in Japanese Patent Application Laid-Open Publication No. 2019-114618 is used, it is necessary to form a detachment-spread-prevention groove on a surface of a terminal that is smaller than a die pad. Thus, it is difficult to form a detachment-spread-prevention groove. When the technique that is disclosed in Japanese Patent Application Laid-Open Publication No. 2018-157023 is used, it is difficult to emit a laser beam to only a terminal within an internal space of a housing to form a roughened region. Thus, a laser beam may be emitted not only to a terminal, but also to a semiconductor element around the terminal. In addition, forming a roughened region having unevenness on the order of micrometers is generally costly. Furthermore, a disadvantage occurs in that a wire is not sufficient coupled to a terminal when a roughened region is formed on a coupling portion of the terminal for the wire. Consequently, when a wet method is used to form a roughened region, a masking process is required to prevent a coupling portion of a terminal for a wire from being roughened. Thus, a process is difficult in which a roughened region is formed. When a laser beam is used to form a roughened region, it is necessary to control a place irradiated by the laser beam with high accuracy to prevent the laser beam from being emitted to a coupling portion of a terminal for a wire. In addition, laser beam irradiation causes adhesion of sputter to a coupling portion of a terminal for a wire and oxidation of the coupling portion of the terminal. Thus, a disadvantage may occur in that a wire is not sufficient coupled to a terminal.

### SUMMARY

An object of one aspect according to the present disclosure is to provide a semiconductor device capable of reducing spreading of detachment of an encapsulant to a coupling portion of a terminal for a wire.

A semiconductor device according to one aspect of the present disclosure includes: a semiconductor element; a terminal to which a wire is coupled; a housing surrounding the semiconductor element and a coupling portion of the terminal, the coupling portion of the terminal being coupled to the wire; and an encapsulant sealing an internal space surrounded by the housing, in which the terminal includes a recess-shaped or protrusion-shaped coupling region including the coupling portion coupled to the wire.

According to one aspect of the present disclosure, it is possible to reduce spread of detachment of an encapsulant toward a coupling portion of a terminal for a wire.

### BRIEF DESCRIPTION OF THE DRAWINGS

FIG. 1 is a schematic cross section of an example of a power semiconductor module according to a first embodiment.

FIG. 2 is an enlarged view of a part of the power semiconductor module indicated by an arrow A shown in FIG. 1.

FIG. 3 is an enlarged view of a vicinity of a protrusion of a terminal shown in FIG. 1 and in FIG. 2.

FIG. 4 is a plan view of an example of a protrusion of each terminal.

FIG. 5 is a schematic diagram showing an example of a portion of a mold, the mold being used to form a housing by insert molding, the portion of the mold covering a protrusion of a terminal.

FIG. 6 is a schematic enlarged view of an example of a cross section of a protrusion of the power semiconductor module according to a second embodiment.

FIG. 7 is a schematic diagram showing an example of a portion of a mold, the mold being used to form a housing by insert molding, the portion of the mold covering a protrusion of a terminal according to the second embodiment.

FIG. 8 is a plan view of an example of a shape of a coupling region according to a first modification.

FIG. 9 is a diagram showing an example of a cross-sectional shape of a stepped portion according to a second modification.

FIG. 10 is a diagram showing another example of a cross-sectional shape of a stepped portion according to the second modification.

### DESCRIPTION OF EMBODIMENTS

Embodiments according to the present disclosure will now be described with reference to the accompanying drawings. In each drawing, dimensions and scales of elements may differ from those of actual products. In addition, each embodiment described below is an exemplary embodiment assumed in a case in which the present disclosure is implemented. Thus, the scope of the present disclosure is not limited to the embodiments described below.

### 1. First Embodiment

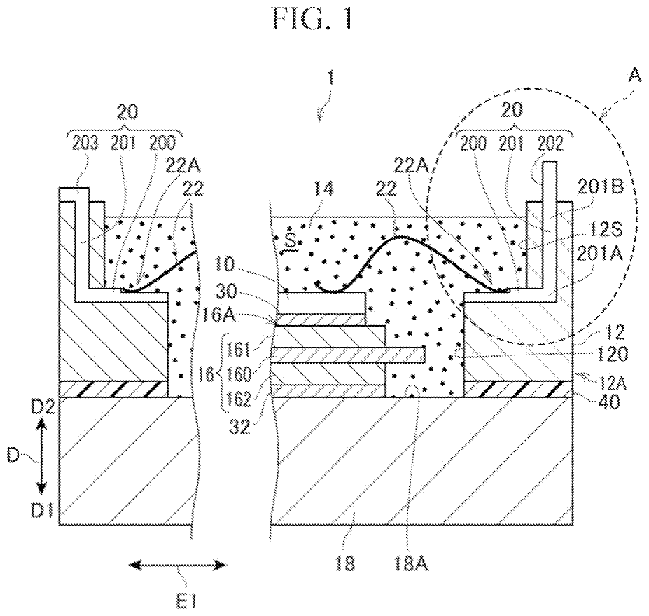

FIG. 1 is a schematic cross section of an example of a power semiconductor module 1 according to a first embodiment. The power semiconductor module 1 is an example of a semiconductor device according to the present disclosure. As shown in FIG. 1, the power semiconductor module 1 is a housing-shaped module. The power semiconductor module 1 includes at least one power semiconductor element 10, a plurality of terminals 20, and a housing 12. Each of the plurality of terminals 20 is coupled to a corresponding metallic wire 22. Specifically, each of the plurality of terminals 20 includes a coupling portion coupled to the corresponding wire 22. The housing 12 surrounds the at least one power semiconductor element 10 and the coupling portion of each of the plurality of terminals 20. The housing 12 defines an internal space S. In other words, the internal space S is surrounded by the housing 12. The internal space S is sealed with an encapsulant 14.

More specifically, the power semiconductor module 1 further includes an insulating substrate 16 and a cooler 18 on which the insulating substrate 16 is disposed. The insulating substrate 16 is coupled to the at least one power semiconductor element 10. The insulating substrate 16 is accommodated in the housing 12. Each of the plurality of terminals 20 is connected to one of the at least one power semiconductor elements 10 or to the insulating substrate 16 via the corresponding wire 22. The housing 12 is disposed on the cooler 18 to surround the at least one power semiconductor element 10 and the insulating substrate 16. The housing 12 is cylinder-shaped and has an end 12A that is disposed on the cooler 18. The end 12A of the housing 12 has an opening 120 that is covered by a substrate mount surface 18A of the cooler 18. In other words, the housing 12 and the cooler 18 constitute a container with a bottom. The container has the internal space S. A liquid encapsulating material is injected into the internal space S of the container. The encapsulating material is cured to form the encapsulant 14.

In the following description, an axial direction of the cylinder-shaped housing 12 is referred to as a “vertical direction D.” In the vertical direction, a direction from a power semiconductor element 10 toward the insulating substrate 16 or toward the cooler 18 may be referred to as a “downward direction D1,” and a direction opposite to the downward direction D1 may be referred to as an “upward direction D2.” In a cross section of the power semiconductor module 1, a direction perpendicular to the vertical direction D may be referred to as a “horizontal direction E1.” The view of the power semiconductor module 1 in the downward direction D1 may be referred to as a “plan view.” In plan view, a direction perpendicular to the horizontal direction E1 may be referred to as a “depth direction E2.”

The at least one power semiconductor element 10 is an example of a semiconductor element according to the present disclosure. The at least one power semiconductor element 10 is, for example, an insulated gate bipolar transistor (IGBT) or a diode chip, etc. The at least one power semiconductor element 10 may be at least one silicon (Si) device. Alternatively, a power semiconductor element 10 of the at least one power semiconductor element 10 may be a wide band gap semiconductor device such as a silicon carbide (SiC) device, a gallium nitride (GaN) device, a diamond device, a zinc oxide (ZnO) device, etc. In a state in which the at least one power semiconductor element 10 comprises two or more power semiconductor elements 10, types of the power semiconductor elements 10 may be the same as or be different from each other. A combination of different types of power semiconductor elements 10 constitutes a so-called hybrid module type of power semiconductor module 1 that includes, for example, a Si-IGBT and a SiC-Schottky Barrier Diode (SBD).

The insulating substrate 16 includes a plate-shaped insulating layer 160 with electric insulation. The insulating substrate 16 has a main surface as a semiconductor coupling surface 16A. In this embodiment, the insulating substrate 16 is a laminated substrate that is a stack of layers in a direction of the thickness of the insulating substrate 16. The insulating substrate 16 further includes a first conductive layer 161 and a second conductive layer 162 in addition to the insulating layer 160. The insulating layer 160 is made of a material that not only has excellent electric insulation, but also has excellent thermal conductivity. This material is, for example, a ceramic plate that is mainly made of alumina (Al₂O₃) material, aluminum nitride (AlN) material, silicon nitride (SiN), etc. The first conductive layer 161 and the second conductive layer 162 are each a layer with electrical conductivity. The first conductive layer 161 is disposed on one main surface of the insulating layer 160. The second conductive layer 162 is disposed on the other main surface of the insulating layer 160. The first conductive layer 161 and the second conductive layer 162 are each made of a material that not only has excellent electrical conductivity, but also has excellent workability. This material is, for example, a material that is mainly made of a metallic material such as a copper (Cu) material, an aluminum (Al) material, etc.

The first conductive layer 161 is disposed on the main surface of two main surfaces of the insulating layer 160, the main surface of the insulating layer 160 facing the semiconductor coupling surface 16A. In plan view, the first conductive layer 161 constitutes a predetermined circuit pattern disposed on the main surface of the insulating layer 160. The first conductive layer 161 is coupled to the at least one power semiconductor element 10 with a solder material 30. In addition, the first conductive layer 161 is connected to at least one of the plurality of terminals 20 via at least one corresponding wire 22. The second conductive layer 162 is disposed on substantially the entire area of the other main surface of the two main surfaces of the insulating layer 160, the other main surface of the insulating layer 160 facing the cooler 18. In this embodiment, the second conductive layer 162 is made of, for example, foil. To stack the first conductive layer 161 and the second conductive layer 162 on one main surface of the insulating layer 160 and the other main surface of the insulating layer 160 respectively, an appropriate method may be used such as a direct copper bonding method, an active metal brazing method, etc. The first conductive layer 161 and the second conductive layer 162 may be subjected to surface treatment such as nickel (Ni) plating for prevention of rust.

The cooler 18 is a member for cooling the at least one power semiconductor element 10. Specifically, the cooler 18 causes a coolant such as water to remove heat from the at least one power semiconductor element 10 to cool the at least one power semiconductor element 10. In this embodiment, the cooler 18 is mainly made of a metallic material such as a Cu material, an Al material, etc. The cooler 18 has flow paths through which the coolant flows. The flow paths are provided inside the cooler 18. The flow paths may be provided on a surface of the cooler 18 rather than inside the cooler 18. The cooler 18 is plate-shaped and has a planar main surface that is used as the substrate mount surface 18A and that is coupled to the insulating substrate 16 with a solder material 32.

The housing 12 is a resin molded component that is mainly made of thermoplastic resin or of thermosetting resin. Examples of the thermoplastic resin are polyphenylene sulfide (PPS), polybutylene terephthalate (PBT), etc. Examples of the thermosetting resin are phenol formaldehyde resin, etc. The end 12A of the housing 12 is separated in the direction D1 from the other end of the housing 12. The end 12A of the housing 12 is bonded to the substrate mount surface 18A of the cooler 18 with an adhesive 40.

Each of the plurality of terminals 20 includes a protrusion 200. The protrusion 200 extends linearly in the horizontal direction E1 from an inner circumferential surface 12S of the housing 12 within the internal space S surrounded by the housing 12. The protrusion 200 is coupled to a corresponding wire 22. Each of the plurality of terminals 20 further includes an embedded portion 201 and an external exposed portion 202 in addition to the protrusion 200 described above. The embedded portion 201 is embedded in the housing 12. The embedded portion 201 is a linear portion extending in the vertical direction D. The embedded portion 201 has one end 201A that is continuous with the protrusion 200. The external exposed portion 202 is continuous with the other end 201B of the embedded portion 201. The external exposed portion 202 is exposed to an outside of the power semiconductor module 1. The embedded portion 201 and the protrusion 200 are continuous with each other at substantially right angles. As a result, each of the plurality of terminals 20 is substantially L-shaped as viewed in cross section. An angle between the embedded portion 201 and the protrusion 200 is not limited to a right angle. The angle between the embedded portion 201 and the protrusion 200 may be greater than 90 degrees. The housing 12 is formed by insert molding such that each of the plurality of terminals 20 is fixed to the housing 12 in a state in which the embedded portion 201 is embedded in the housing 12. The power semiconductor module 1 may further include a terminal that is to be retrofitted after formation of the housing 12, in other words, a terminal not having a portion embedded in the housing 12.

The wires 22 are each a thin wire that is mainly made of a metallic material such as an Al material. To couple one end 22A of each of the wires 22 and a corresponding terminal 20 to each other, wire bonding such as ultrasonic bonding is used. At least one of the plurality of terminals 20 may be coupled to a conductive member, which is referred to as a lead, that is wider than a corresponding wire 22, instead of the corresponding wire 22.

The encapsulant 14 protects elements disposed within the internal space S from influences of the environment. The elements include the at least one power semiconductor element 10, the insulating substrate 16, the protrusion 200 of each of the plurality of terminals 20, the wires 22, a place coupled to one end of each of the wires 22, and a place coupled to the other end of each of the wires 22. The encapsulant 14 improves mechanical strength of each of the elements. The encapsulant 14 electrically insulates the elements. As a method for forming an encapsulant, a vacuum injection method, a transfer molding method, a liquid transfer molding method, a potting method, etc., are known in a technical field of semiconductor devices. In this embodiment, the encapsulant 14 is molded by use of a potting method, which is not required to use a mold, among these molding methods. In a potting method, after each element such as the at least one power semiconductor element 10 is disposed within the internal space S and wiring for the wires 22 is completed, an encapsulating material is injected into the internal space S.

In this embodiment, the encapsulating material is made of thermosetting resin that is a kind of curable resin. Specifically, the encapsulating material is made of epoxy resin rather than silicone gel, epoxy resin and silicone gel being each a kind of thermosetting resin. The encapsulant 14 that is mainly made of epoxy resin does not readily absorb moisture compared to an encapsulant that is mainly made of silicone gel. Thus, the encapsulant 14 can be expected to have an advantage of preventing elements encapsulated by the encapsulant 14 from being degraded due to moisture in the encapsulant 14. In addition, the encapsulant 14 can substantially prevent the elements encapsulated by the encapsulant 14 from being degraded due to thermocycling. Thus, the encapsulant 14 can improve reliability of the power semiconductor module 1.

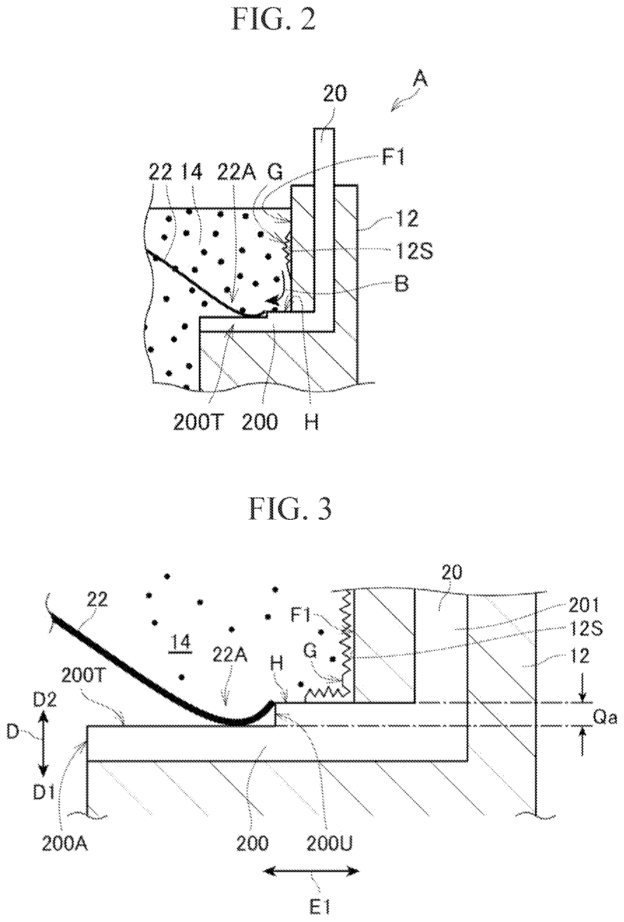

FIG. 2 is an enlarged view of a part of the power semiconductor module 1 indicated by an arrow A shown in FIG. 1. In the following description, an interface between the protrusion 200 and the encapsulant 14 may be referred to as a “terminal-encapsulant interface H”, and an interface between the inner circumferential surface 12S of the housing 12 and the encapsulant 14 may be referred to as a “first case-encapsulant interface F1.” As shown in FIG. 2, the protrusion 200 of the terminal 20 protrudes from the inner circumferential surface 12S of the housing 12 within the internal space S of the housing 12. Thus, the terminal-encapsulant interface H and the first case-encapsulant interface F1 are continuous with each other at a starting point of the protrusion 200. As a result, when detachment G may occur at a part of the first case-encapsulant interface F1 due to thermal stress caused by a difference between a thermal expansion coefficient of the housing 12 and a thermal expansion coefficient of the encapsulant 14 in a thermocycling test (−40 to 125 degrees Celsius), etc., the detachment G may spread toward the terminal 20 as indicated by an arrow B to reach the terminal-encapsulant interface H. The detachment G may then spread on the terminal-encapsulant interface H. Thus, if no measures are taken, the detachment G may reach a coupling portion of the protrusion 200, the coupling portion of the protrusion 200 being coupled to the end 22A of the wire 22, resulting in breakage of the wire 22 at the coupling portion of the protrusion 200.

In this embodiment, the protrusion 200 includes at least one structure for delaying or preventing spread of detachment G to the coupling portion of the protrusion 200 coupled to the end 22A of the wire 22, resulting in substantially preventing breakage of the wire 22. The at least one structure will be described in detail below.

FIG. 3 is an enlarged view of a vicinity of the protrusion 200 of the terminal 20 shown in FIG. 1 and in FIG. 2. As shown in FIG. 3, the protrusion 200 of the terminal 20 includes a coupling region 200T that is coupled to a corresponding wire 22. The entire area of the coupling region 200T is formed to be recess-shaped by, for example, a pressing process in which a surface of the protrusion 200 is pressed. As a result, in cross section, the protrusion 200 includes a stepped portion 200U having a difference Qa between a level of a surface of the coupling region 200T and a level of a surface of the protrusion 200 other than the surface of the coupling region 200T. When detachment G reaches the stepped portion 200U, the following two phenomena occur together with each other. In the first phenomenon, the stepped portion 200U changes a direction of spread of the detachment G to a direction other than a direction of the coupling region 200T, resulting in preventing or delaying spread of the detachment G to a coupling portion of the coupling region 200T, the coupling portion of the coupling region 200T being coupled to the wire 22. In the second phenomenon, the stepped portion 200U functions as a resistance to spread of the detachment G, resulting in preventing or delaying spread of the detachment G to the coupling portion of the coupling region 200T. Since the first phenomenon and the second phenomenon occur, it is possible to prevent, or to delay, breakage of the wire 22 caused by spreading of the detachment G.

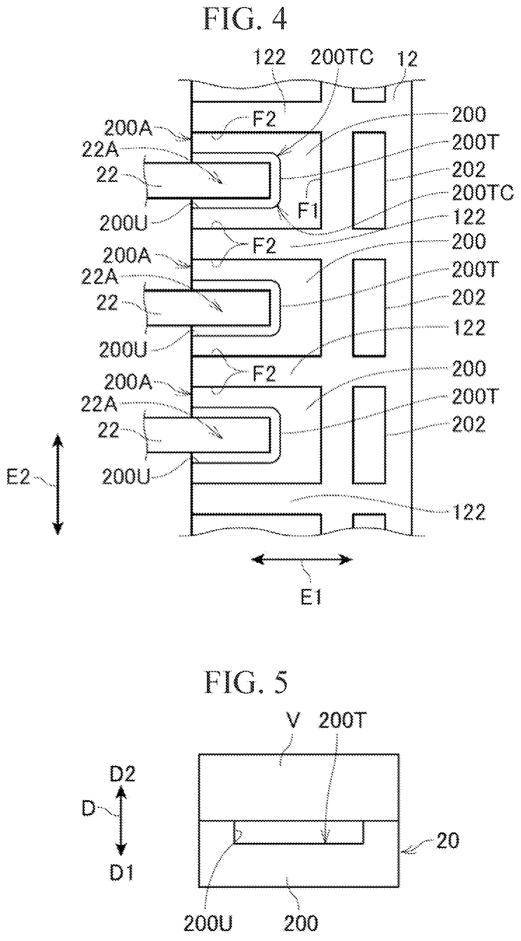

FIG. 4 is a plan view of an example of a protrusion 200 of each terminal 20. The protrusion 200 includes a coupling region 200T. In plan view, the coupling region 200T is substantially rectangular. In this embodiment, the power semiconductor module 1 includes two or more terminals 20 that are included in the plurality of terminals 20. In plan view, the two or more terminals 20 are arranged in the depth direction E2. The housing 12 includes a plurality of partitions 122. Each of the plurality of partitions 122 is disposed between two adjacent terminals 20 among the two or more terminals 20. The two or more terminals 20 are physically and electrically isolated from each other by the plurality of partitions 122. In this configuration, the interface between the housing 12 and the encapsulant 14 includes not only the first case-encapsulant interface F1, but also an interface between each of the plurality of partitions 122 and the encapsulant 14. Detachment G may occur at a part of an interface between one of the plurality of partitions 122 and the encapsulant 14. In the following description, the interface between each of the plurality of partitions 122 and the encapsulant 14 may be referred to as “second case-encapsulant interface F2.”

In the protrusion 200 according to this embodiment, the entire area of the coupling region 200T is recess-shaped, and a stepped portion 200U is formed to extend along an edge of the coupling region 200T and to be disposed not only between a corresponding first case-encapsulant interface F1 and the coupling region 200T, but also between each of two corresponding second case-encapsulant interfaces F2 and the coupling region 200T. Thus, when detachment G occurs at a part of one of the two second case-encapsulant interfaces F2 and then the detachment G spreads toward a corresponding terminal-encapsulant interface H, the stepped portion 200U can prevent, or can delay, spread of the detachment G.

In plan view, the coupling region 200T according to this embodiment has rounded corners 200TC and has a rounded-rectangular shape. Since the coupling region 200T is rounded-rectangle-shaped, it is possible to substantially prevent thermal stress, described above, from being concentrated at each of the rounded corners 200TC and to reduce spread of detachment G, compared to a configuration in which each of the corners 200TC has a right angle in plan view. Curvature of each of the corners 200TC may be changed as appropriate.

The stepped portion 200U adjacent to the coupling region 200T has an advantage in that the stepped portion 200U can prevent, or can delay, spread of detachment G. The advantage is greater with an increase in size of a corresponding difference Qa. However, with an increase in size of the difference Qa, a process of coupling a corresponding wire 22 by wire bonding decreases in work efficiency. Thus, in this embodiment, the difference Qa is set to the same as a diameter of the wire 22, resulting in preventing a process of coupling the wire 22 by wire bonding from decreasing in work efficiency. More specifically, in this embodiment, a thickness of the protrusion 200 in the vertical direction D is between 500 μm and 1 mm. In plan view, a size of the coupling region 200T is about 3 mm in the horizontal direction E1 and is about 2 mm in the depth direction E2 perpendicular to the horizontal direction E1. The coupling region 200T with these dimensions is coupled to the wire 22 having a diameter between about 100 μm and 300 μm. In this case, the difference Qa is between about 100 μm and 300 μm as well as the diameter of the wire 22. The difference Qa and the diameter of the wire 22 are not required to be identical to each other. The difference Qa may differ from the diameter of the wire 22 by several percent, or by tens of percent, of the diameter of the wire 22.

As shown in FIG. 3 and in FIG. 4, the recess-shaped coupling region 200T according to this embodiment is continuous with an end 200A of the protrusion 200. In other words, the recess-shaped coupling region 200T has a portion that is adjacent to the end 200A of the protrusion 200, the portion of the coupling region 200T being in contact with to the internal space S and not being continuous with the stepped portion 200U. As a result, it is possible to improve work efficiency in a process of coupling the wire 22.

FIG. 5 is a schematic diagram showing an example of a portion V of a mold, the mold being used to form the housing 12 by insert molding, the portion V of the mold covering a protrusion 200 of a terminal 20. The housing 12 is an insert molded component that is integrally formed, together with the plurality of terminals 20, by insert molding. In this insert molding process, the housing 12 is formed in a state in which the wires 22 are inserted in the mold, each of the wires 22 having a protrusion 200 with a recess-shaped coupling region 200T. In this insert molding process, as shown in FIG. 5, the portion V of the mold is in contact with a surface of the protrusion 200 of the terminal 20, resulting in covering an open surface of the recess-shaped coupling region 200T in the upward direction D2. Although not shown, another portion of the mold covers an open portion of an end 200A of the protrusion 200 in the coupling region 200T. In other words, in the insert molding process according to this embodiment, all open portions of the recess-shaped coupling region 200T are covered by portions of the mold. Thus, it is possible to prevent resin powder, which is a material of the housing 12, from entering the coupling region 200T and adhering to the coupling region 200T. As a result, in forming the housing 12 by insert molding, postprocessing may not be required in which the resin powder is removed from the coupling region 200T.

As described above, the power semiconductor module 1 according to this embodiment includes the power semiconductor element 10, a terminal 20 to which a wire 22 is coupled, the housing 12, and the encapsulant 14. The housing 12 surrounds the power semiconductor element 10 and a coupling portion of the terminal 20, the coupling portion being coupled to the wire 22. The encapsulant 14 seals the internal space S surrounded by the housing 12. In the power semiconductor module 1, the terminal 20 includes a recess-shaped coupling region 200T including the coupled portion coupled to the wire 22. According to this configuration, the terminal 20 includes the stepped portion 200U via which the surface of the coupling region 200T and the surface of the protrusion 200 are connected to each other. Thus, when detachment G spreads on the protrusion 200, the stepped portion 200U changes a direction of the spread of the detachment G to a direction other than a direction of the coupling region 200T or the stepped portion 200U functions to resist the spread of the detachment G. As a result, it is possible to prevent, or to delay, spread of the detachment G to the coupling portion of the coupling region 200T, the coupling portion being coupled to the wire 22.

In this embodiment, the terminal 20 further includes the embedded portion 201, which is embedded in the housing 12, and the protrusion 200 that is continuous with the embedded portion 201 and that extends within the internal space S, and the protrusion 200 includes the recess-shaped coupling region 200T. In this configuration, the interface between the protrusion 200 and the encapsulant 14 (terminal-encapsulant interface H) is continuous with the interface between the housing 12 and the encapsulant 14 (first case-encapsulant interface F1). Thus, when detachment G occurs at the first case-encapsulant interface F1 and then the detachment G spreads toward the terminal-encapsulant interface H, it is possible to prevent, or to delay, spread of the detachment G to the coupling portion of the coupling region 200T.

In this embodiment, the housing 12 is an insert molded component in which a portion of the terminal 20 is embedded. According to this configuration, it is possible to form the housing 12 by insert molding in a state in which a mold for insert molding covers the recess-shaped coupling region 200T that has been formed on the terminal 20 in advance. Thus, it is possible to prevent resin powder, etc., of the housing 12 from adhering to the coupling region 200T in forming the housing 12 by insert molding. As a result, postprocessing may not be required in which the resin powder is removed from the coupling region 200T.

In this embodiment, the recess-shaped coupling region 200T is continuous with the end 200A of the terminal 20. According to this configuration, the recess-shaped coupling region 200T has a portion that is adjacent to the end 200A of the protrusion 200, the portion of the coupling region 200T being in contact with to the internal space S and not being continuous with the stepped portion 200U. As a result, it is possible to improve work efficiency in a process of coupling the wire 22.

In this embodiment, the housing 12 is cylinder-shaped, and the recess-shaped coupling region 200T has a rounded-rectangular shape in plan view in a direction of an axis of the housing 12. According to this configuration, it is possible to substantially prevent thermal stress caused by thermocycling from being concentrated at each of the rounded corners 200TC and to reduce spread of detachment G, compared to a configuration in which the coupling region 200T is rectangular in plan view.

In this embodiment, the difference Qa between the level of the recess-shaped coupling region 200T and the level of the surface of the terminal 20 corresponds to the diameter of the wire 22. According to this configuration, it is possible to prevent a process of coupling the wire 22 from decreasing in work efficiency.

### 2. Second Embodiment

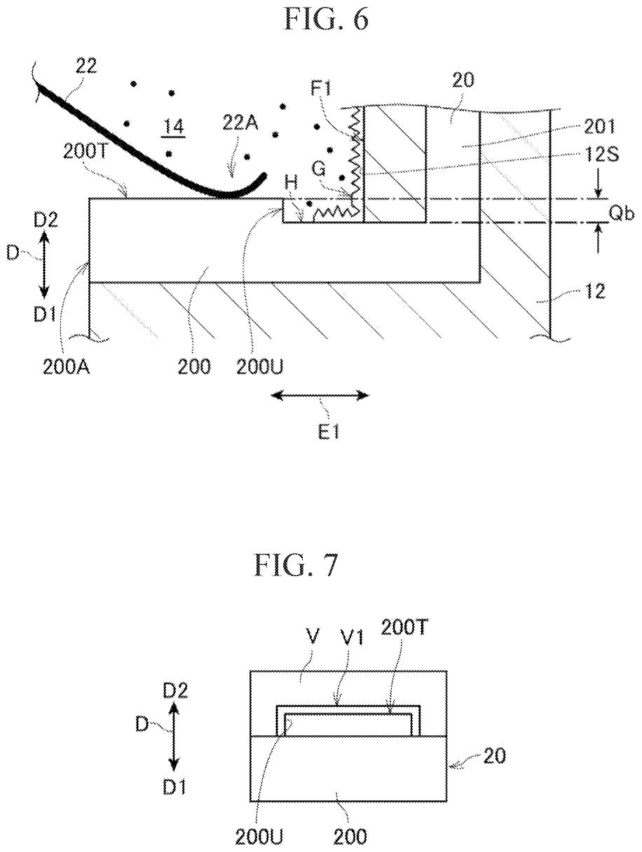

FIG. 6 is a schematic enlarged view of an example of a cross section of a protrusion 200 of the power semiconductor module 1 according to a second embodiment. In FIG. 6, elements described in the first embodiment will be denoted by the same reference signs used in the description of the embodiment described above, and detailed description thereof will be omitted as appropriate. In the first embodiment, the coupling region 200T of the protrusion 200 is recess-shaped in the downward direction D1. In contrast, the entire coupling region 200T according to the second embodiment is protrusion-shaped in the upward direction D2. In other words, the second embodiment differs from the first embodiment in that coupling region 200T is protrusion-shaped. As in the first embodiment, in the second embodiment, the protrusion 200 includes the stepped portion 200U having a difference Qb between a level of a surface of the coupling region 200T and a level of a surface of the protrusion 200 other than the surface of the coupling region 200T. Thus, as in the first embodiment, in the second embodiment, when detachment G spreads toward the terminal-encapsulant interface H, the stepped portion 200U can prevent, or to delay, spread of the detachment G to the coupling portion of the coupling region 200T, the coupling portion being coupled to the wire 22.

The protrusion-shaped coupling region 200T is continuous with the end 200A of the protrusion 200. According to this configuration, there is no unevenness between the end 200A of the protrusion 200 and the coupling region 200T in the horizontal direction E1. As a result, it is possible to prevent a process of coupling the wire 22 decreasing in work efficiency. In plan view, the protrusion-shaped coupling region 200T is rounded-rectangle-shaped as in the first embodiment. Thus, it is possible to substantially prevent thermal stress from being concentrated at each of the rounded corners 200TC.

The protrusion-shaped coupling region 200T is formed by a pressing process in which a portion of a surface of the protrusion 200, which is present in a vicinity of the coupling region 200T, is pressed so as to be dented. In this case, the stepped portion 200U has an advantage in that the stepped portion 200U can prevent, or can delay, spread of detachment G. The advantage is more effective as the size of the difference Qb increases, similarly to the difference Qa in the first embodiment. However, the greater the size of the difference Qb, the greater the dent will be in the portion of the protrusion 200 that is present in the vicinity of the coupling region 200T. Thus, it is difficult to process the protrusion 200. In the second embodiment, the difference Qb is less than a thickness of the protrusion 200 in the vertical direction D and the difference Qb is set to be the same as the diameter of the wire 22. In the second embodiment, the thickness of the protrusion 200 in the vertical direction D is between 500 μm and 1 mm. The diameter of the wire 22 is between about 100 μm and 300 μm. The difference Qb of the stepped portion 200U adjacent to the coupling region 200T is between about 100 μm and 300 μm as well as the diameter of the wire 22. The difference Qb and the diameter of the wire 22 are not required to be identical to each other. The difference Qb may differ from the diameter of the wire 22 by several percent or tens of percent of the diameter of the wire 22.

FIG. 7 is schematic diagram showing an example of a portion V of a mold, the mold being used to form the housing 12 by insert molding, the portion V of the mold covering a protrusion 200 of a terminal 20 according to the second embodiment. As shown in FIG. 7, the portion V of the mold includes a recess V1 that is in contact with a surface of the protrusion 200 of the terminal 20. In forming the housing 12 by insert molding, the protrusion-shaped coupling region 200T is covered with the recess V1. Thus, in the insert molding process according to the second embodiment, it is possible to prevent resin powder, which is a material of the housing 12, from adhering to the coupling region 200T, as in the insert molding process according to the first embodiment. As a result, in forming the housing 12 by insert molding, post-processing may not be necessary in which the resin powder is removed from the coupling region 200T.

### 3. Modifications

Specific modified modes that may be applied to each of the embodiments described above are described below. Two or more modifications freely selected from the following modifications may be combined as long as no conflict arises from such a combination.

### First Modification

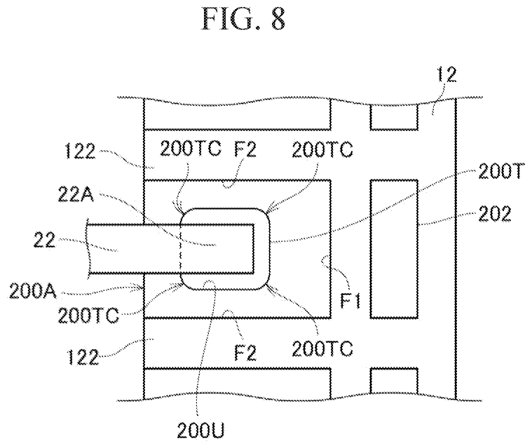

In each of the embodiments, a configuration is described in which the coupling region 200T extends to the end 200A of the protrusion 200. However, as shown in FIG. 8, the coupling region 200T may be formed such that the entire coupling region 200T is present within the protrusion 200 in plan view. In each of the embodiments, the coupling region 200T is not limited to being rectangular in plan view. The coupling region 200T may be changed as appropriate. For example, the coupling region 200T may be ellipse-shaped in plan view.

### Second Modification

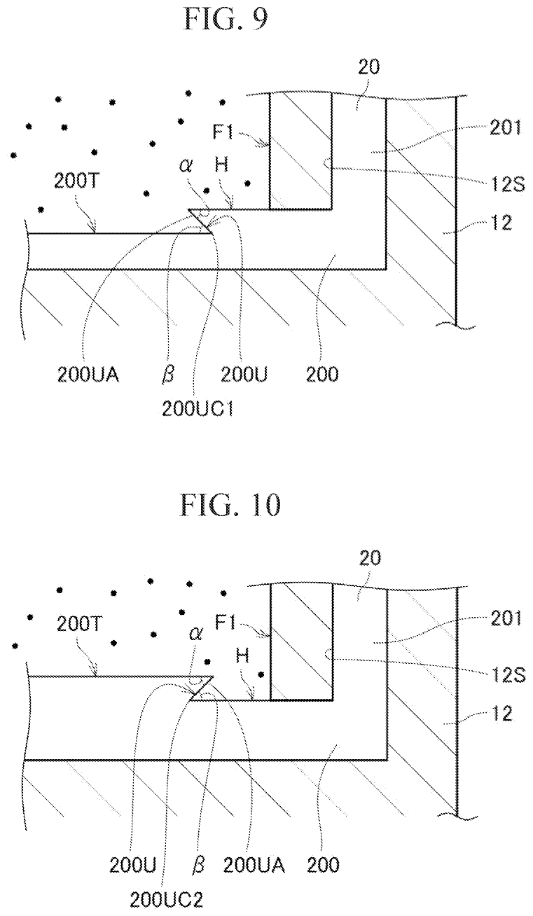

As shown in FIG. 9 and in FIG. 10, in each of the embodiments, the stepped portion 200U surrounding the coupling region 200T has a stepped surface 200UA. The stepped surface 200UA may be inclined such that a first angle α between the stepped surface 200UA and the surface of the protrusion 200 (a surface constituting the terminal-encapsulant interface H) is an acute angle. In other words, the stepped surface 200UA may be inclined such that a second angle β between the stepped surface 200UA and the surface of the coupling region 200T is an acute angle (an angle that is less than 90 degrees).

For example, as shown in FIG. 9, when the coupling region 200T is recess-shaped and the first angle α is an acute angle, the recess-shaped coupling region 200T has, in cross section, a nearly trapezoidal shape, with the base in the downward direction D1 that is longer than the top side in the upward direction D2. The stepped surface 200UA and the coupling region 200T intersect at a corner 200UC1. In the configuration shown in FIG. 9, the corner 200UC1 is positioned under the surface (the surface constituting the terminal-encapsulant interface H) of the protrusion 200. Thus, the encapsulant 14 on the coupling region 200T is hooked on the corner 200UC1. As a result, it is possible to greatly enhance adhesion of the encapsulant 14 to the coupling region 200T. Consequently, it is possible to significantly prevent, or to delay, spread of detachment G on the coupling region 200T.

Alternatively, as shown in FIG. 10, when the coupling region 200T is protrusion-shaped and the first angle α is an acute angle, the stepped surface 200UA and the surface (the surface constituting the terminal-encapsulant interface H) of the protrusion 200 intersect at a corner 200UC2. In cross section, the corner 200UC2 is positioned under the coupling region 200T. Thus, the encapsulant 14 on the terminal-encapsulant interface H is hooked on the corner 200UC2. Accordingly, the encapsulant 14 remains in contact with the coupling region 200T. As a result, it is possible to greatly enhance adhesion of the encapsulant 14 to the terminal-encapsulant interface H. Consequently, it is possible to significantly prevent, or to delay, spread of detachment G to the coupling region 200T.

The recess-shaped coupling region 200T shown in FIG. 9 and the protrusion-shaped coupling region 200T shown in FIG. 10 can each be formed by a plurality of pressing processes in each of which the protrusion 200 of the terminal 20 is pressed. For example, the coupling region 200T with the first angle α of substantially 90 degrees is formed by one or more pressing processes, and then the stepped surface 200UA with the first angle α of an acute angle is formed by one or more pressing processes. In this case, the difference Qa of the stepped portion 200U of the recess-shaped coupling region 200T and the difference Qb of the stepped portion 200U of the protrusion-shaped coupling region 200T are each set such that the stepped portion 200U, which has the stepped surface 200UA with the first angle α of an acute angle, is formed by a plurality of pressing processes in which the terminal 20 is repeatedly pressed. For example, when a thickness of the terminal 20 is between 500 μm and 1 mm, each of the differences Qa and Qb is set to be greater than or equal to 10 μm and less than or equal to 100 μm.

### Third Modification

In each of the embodiments, a configuration is described in which the protrusion 200 of the terminal 20 includes the recess-shaped or protrusion-shaped coupling region 200T, the terminal 20 having the portion embedded in the housing 12, the terminal 20 and the housing 12 constituting a single member. However, the terminal 20 may be separated from the housing 12. In other words, a portion of the terminal 20 may not be embedded in the housing 12. In this case, the terminal 20 includes the recess-shaped or protrusion-shaped coupling region 200T coupled to the wire 22. Thus, when detachment G spreads on the surface of the terminal 20, it is possible to prevent, or to delay, spread of the detachment G to the coupling portion of the coupling region 200T, the coupling portion being coupled to the wire 22.

### DESCRIPTION OF REFERENCE SIGNS

1 . . . power semiconductor module, 10 . . . power semiconductor element, 12 . . . housing, 12S . . . inner circumferential surface, 14 . . . encapsulant, 20 . . . terminal, 22 . . . wire, 200 . . . protrusion, 200A . . . end, 200T . . . coupling region, 200TC . . . corner, 200U . . . stepped portion, 200UA . . . stepped surface, 201 . . . embedded portion, G . . . detachment, Qa, Qb . . . difference, S . . . internal space, α . . . first angle.

What is claimed is:

1. A semiconductor device comprising:
a semiconductor element;
a terminal to which a wire is coupled;
a housing surrounding the semiconductor element and a coupling portion of the terminal, the coupling portion of the terminal being coupled to the wire; and
an encapsulant sealing an internal space surrounded by the housing,
wherein the terminal includes a recess-shaped or protrusion-shaped coupling region including the coupling portion coupled to the wire.

2. The semiconductor device according to claim 1,
wherein the terminal further includes:
an embedded portion embedded in the housing; and
a protrusion that is continuous with the embedded portion, the protrusion extending within the internal space, and
wherein the protrusion includes the recess-shaped or protrusion-shaped coupling region.

3. The semiconductor device according to claim 1, wherein the housing is an insert molded component in which a portion of the terminal is embedded.

4. The semiconductor device according to claim 1, wherein the recess-shaped or protrusion-shaped coupling region is continuous with an end of the terminal.

5. The semiconductor device according to claim 1,
wherein the housing is cylinder-shaped, and
wherein the recess-shaped or protrusion-shaped coupling region has a rounded-rectangular shape in plan view in a direction of an axis of the housing.

6. The semiconductor device according to claim 1, wherein a difference between a level of the recess-shaped or protrusion-shaped coupling region and a level of a surface of the terminal corresponds to a diameter of the wire.

7. The semiconductor device according to claim 1,
wherein the recess-shaped or protrusion-shaped coupling region is connected to a surface of the terminal via a stepped surface, and
wherein an angle between the stepped surface and the surface of the terminal is an acute angle.
